(19) United States
(12) Patent Application Publication
(10) Pub. No.: US 2001/0030883 A1
(43) Pub. Date: Oct. 18, 2001

(54) IC memory card and electronic apparatus using the same

(76) Inventors: Shin Iima, Tokyo (JP); Hirofumi Kanemaki, Kanagawa (JP); Makoto Saito, Tokyo (JP)

Correspondence Address: William S. Frommer, Eaq., FROMMER LAWRENCE & HAUG LLP, 745 FIFTH AVENUE, NEW YORK, NY, 10151, US

(21) Appl. No.: 09/774,997

(22) Filed: Jan. 31, 2001

(30) Foreign Application Priority Data
Feb. 1, 2000 (JP) 2000-028951

(51) Int. Cl. G11C 5/02

(52) U.S. Cl. 365/51

(57) ABSTRACT

An IC memory card comprising a case and a semiconductor memory device therein, able to be loaded into an electronic apparatus to exchange data with the apparatus, able to store data in the semiconductor memory device, and able to be carried outside the apparatus, wherein a through-hole for passing a card connection means for holding use is formed in the case, the function of the through-hole is diversified, the through-hole is utilized as a detection mark when identifying the type of card, a slide shutter having the function of a protection switch is provided, or an opening and closing device is provided at the through-hole itself for passing the closed card connection means, whereby carrying of a number of cards together is facilitated and. handling and storage are improved.

### BACKGROUND OF THE INVENTION

1. Field of the Invention

The present invention relates to an IC memory card with a built-in semiconductor memory device and an electronic apparatus using the same as a portable storage medium.

2. Descriptions of the Related Art

IC memory cards are known as portable mass storage media having built-in flash memories and other electrically programable nonvolatile semiconductor memory devices.

Each kind of IC memory card of the related art is often exclusively used for a certain kind of apparatus, such as prepaid cards, ID cards, etc., that store charging information, personal information, and so on.

Recently, however, due to striking progress in fields such as network household appliances, digital AV apparatuses, and mobile information apparatuses, in which personal computers play central roles, IC memory cards are attracting attention as a kind of versatile medium for exchanging various kinds of data including sound, images, and communication data among all kinds of electronic apparatuses.

IC memory cards of quite a few standards are proposed for rapid expansion of such applications. As typical existing IC memory cards, for example, there are the Memory Stick, SmartMedia, CompactFlash, Miniature Card, Multimedia Card, SD memory card, and so on.

Along with the greatly increased capacities of nonvolatile memory devices and greatly decreased size of mobile information apparatuses, the more newly proposed the IC memory cards, the smaller the sizes.

On the other hand, the information being dealt with is also greatly diversifying. In the near future, each person will own and use several IC memory cards carrying different types of information.

In such a situation, for prevention of loss of cards or for consideration of handling and storage, it is expected that a person will carry a number of IC memory cards all together.

Existing IC memory cards, however, were not designed taking into consideration being carried around with several other cards.

### SUMMARY OF THE INVENTION

An object of the present invention is to provide an IC memory card easy to carry together with other cards and superior in handling and storage and an electronic apparatus using the same.

According to a first aspect of the present invention, there is provided an IC memory card comprising a case and a semiconductor memory device therein, able to be loaded into an electronic apparatus for exchange of data with the apparatus, able to store data in the semiconductor memory device, and able to be carried outside the apparatus, wherein a through-hole for passing a card connection means for holding use is formed in the case.

The through-hole is provided in the case or in a portion of the case projecting outwards.

Preferably, the walls of the through-hole function as a reinforcing rib when the front and back plates of the case are bonded together.

Alternatively, the case including the walls of the through-hole is formed as a single piece. The case may be comprised of an insulating or a conductive material.

The through-hole may be formed in a portion of the IC memory card out of or inside the electronic apparatus when the IC memory card is loaded in the apparatus.

A number of IC memory cards formed in this way are carried and stored together using a card connection means having a specific shape and comprised of a specific material such as a strap, a wire, or a cord. Namely, by passing the card connection means through the through-holes of the IC memory cards, these IC memory cards will not become scattered and become hard to be lose and easier to handle. When storing the cards, storability is improved by just hanging the card connection means on a hook just like the usual way in which keys are used.

In practical use, a card to be used may be removed from the card connection means for a while and loaded into an electronic apparatus. Alternatively, some or all of the IC memory cards may be loaded into the electronic apparatus without being removed from the card connection means. When an IC memory card is loaded in an electronic apparatus, if a portion of the card sticks out of the apparatus, it is desired to form the through-hole in this portion.

Generally, the through-hole is formed at a location on the case where the hole does not interfere with the arrangement of electronic parts. It is sufficient to give the walls of the through-hole in the case enough strength to serve as a reinforcing rib. In addition, if the case and the through-hole are formed as a single piece by for example a plastic, it is able to fabricate the card at a low cost. Furthermore, the region around the through-hole or the entire body of the case may be made by a conductive material so as to remove the charge when the card is loaded into an electronic apparatus.

According to a second aspect of the present invention, there is provided an IC memory card comprising a case and a semiconductor memory device therein, able to be loaded into an electronic apparatus for exchange of data with the apparatus, able to store data in the semiconductor memory device, and able to be carried outside the apparatus, wherein a through-hole for passing a card connection means for holding use is formed in the card and the interior space of the case holding the semiconductor memory device is separated from the exterior space by the walls of the through-hole to create a closed structure.

An IC memory card formed in this way maintains the air-tightness in the interior space of the case where the built-in semiconductor memory device is located, therefore moisture or dust etc. cannot enter the inside of the card even though a through-hole is made in the case.

According to a third aspect of the present invention, there is provided an IC memory card comprising a case and a semiconductor memory device therein, able to be loaded into an electronic apparatus for exchange of data with the apparatus, able to store data in the semiconductor memory device, and able to be carried outside the apparatus, further comprising a through-hole formed in the case for passing a card connection means for holding use and determined in shape and/or position according to the type of the IC memory card so that the card is capable of being recognized when it: is loaded in the electronic apparatus.

According to a fourth aspect of the present invention, there is provided an IC memory card comprising a case and a semiconductor memory device therein, able to be loaded into an electronic apparatus for exchange of data with the apparatus, able to store data in the semiconductor memory device, and able to be carried outside the apparatus, further comprising a through-hole formed in the case for passing a card connection means for holding use and a slide-shutter provided at one or both ends of the through-hole in the axial direction and also serving as a protection switch for preventing the data stored in the IC memory card from being read and/or overwritten.

According to a fifth aspect of the present invention, there is provided an IC memory card comprising a case and a semiconductor memory device therein, able to be loaded into an electronic apparatus for exchange of data with the apparatus, able to store data in the semiconductor memory device, and able to be carried outside the apparatus, further comprising a through-hole formed in the case for passing a card connection means for holding use, a guide provided between the through-hole and one of the sidewalls of the case and through the front and back plates of the case and for passing said card connection means, and a slide gate for opening the guide when the card connection means is to pass through the through-hole and for closing the guide after the card connection means passes through the through-hole.

In IC memory cards according to the third and the fourth aspects, the through-holes are not only for passing the card connection means, but are formed as versatile through-holes combining a function as a detection mark when identifying the type of cards and a function as a protection switch. In addition, in the IC memory card according to the fifth aspect, a through-hole capable of being opened and closed is formed, hence only the necessary IC memory card can be removed easily from the closed ring shaped card connection means. In this case, since the card connection means is a closed ring shape, the IC memory cards that are not to be used at the present will not be scattered.

According to a sixth aspect of the present invention, there is provided an electronic apparatus including a card loading unit for loading an IC memory card storing data in a built-in semiconductor memory device and a space for holding a card connection means for holding use close to the card loading unit when the IC memory card is loaded in a state where the card connection means is passed through a through-hole provided in the case.

By providing such space, the entire IC memory card is able to be loaded in the apparatus with it still being passed through by the card connection means. In addition, for example, it is possible to provide a mechanism for holding the card connection means in the space. In this case, there will be no force exerted on the IC memory card loaded in the apparatus via the card connection means.

According to a seventh aspect of the present invention, there is provided an electronic apparatus comprising a card loading unit for loading an IC memory card storing data in a built-in semiconductor memory device and a hole detector for detecting a through-hole provided in the case for passing a card connection means for holding use after the IC memory card is loaded.

### BRIEF DESCRIPTION OF THE DRAWINGS

These and other objects and features of the present invention will become clearer from the following description of the referred embodiments given with reference to the accompanying drawings, in which:

FIG. 1 is a perspective view of an IC memory card according to the first embodiment held by a card connection means;

FIG. 2 is a schematic cross-sectional view of an IC memory card according to the first embodiment;

FIG. 3 is a perspective view of an IC memory card according to the second embodiment held by a card connection means;

FIG. 4 is a perspective view of an IC memory card according to the second embodiment loaded in a mobile phone;

FIGS. 5A and 5B are plan views of IC memory cards according to the third embodiment in which positions of the through-holes are changed according to the type of card;

FIGS. 6A to 6C are plan views of IC memory cards according to the third embodiment in which shapes of the through-holes are changed according to the type of card;

FIG. 7 is a perspective view of an IC memory card according to the third embodiment loaded in a mobile phone;

FIG. 8 is a perspective view of an IC memory card according to the fourth embodiment; and

FIG. 9 is a perspective view of an IC memory card according to the fifth embodiment.

### DESCRIPTION OF THE PREFERRED EMBODIMENTS

Below, preferred embodiments of an IC memory card and an electronic apparatus according to the present invention will be described with reference to the accompanying drawings taking as an example a mobile phone as the electronic apparatus.

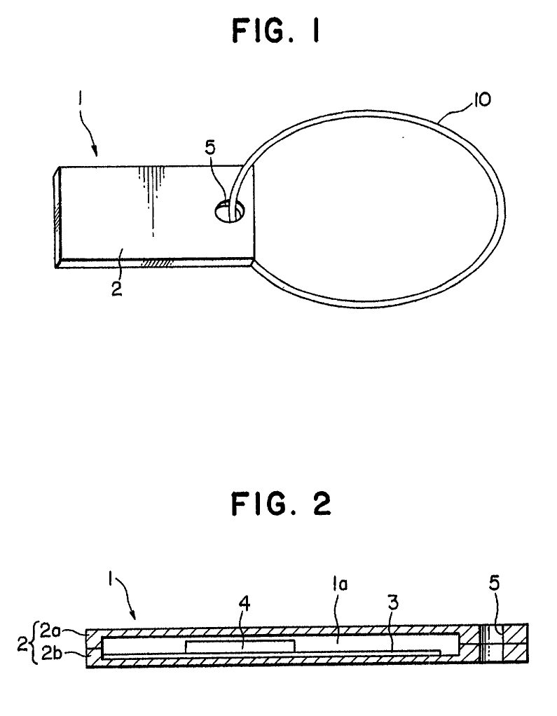

First Embodiment FIG. 1 is a view of an IC memory card according to the first embodiment held by a card connection means. FIG. 2 is a schematic cross-sectional view of the IC memory card.

The size of the IC memory card shown in these figures, for example, ranges from about 32 mm×24 mm to 21.5 mm×50 mm. As examples of existing IC memory cards, the Memory Stick has a size of 21.5 mm×50 mm, SmartMedia 45 mm×37 mm, CompactFlash 36.4 mm×42.8 mm, Miniature Card 33 mm×38 mm, Multimedia Card 32 mm×24 mm, and SD memory card 32 mm×24 mm. The thicknesses of these cards are from 0.76 mm to 3.3 mm.

As shown in FIG. 2, in an IC memory card 1, a substrate (or a film) 3 on which electronics parts are arranged is placed in a case 2. The electronics parts include, for example, semiconductor memory devices 4 such as flash memory IC's etc., IC's for control, and so on. The number of the semiconductor memory devices is decided according to the capacity of the present IC memory card (for example, 8 Mbytes, 10 Mbytes, 16 Mbytes, 32 Mbytes, 48 Mbytes, and 64 Mbytes).

In this example, although it may also be formed as a single piece, the case 2 is formed by bonding together case pieces 2a and 2b leaving its inside empty. Therefore, a space 1a is formed inside the case. In this space, the substrate 3 and electronic parts including the semiconductor memory device 4 are arranged. Along the peripheral region of the case 2, where the case pieces 2a and 2b are in contact and bonded, the bonding area at one side is made larger than at the other three sides. This bonding region functions as a reinforcing rib. With this reinforcing rib, the overall strength of the case is raised. In addition, for example, the direction of printing on the surface of the case may be decided or an arrow may be added to indicate the direction of loading, so that this reinforced side is handled and as a result the frequency of handling the hollow part can be reduced.

The case 2 is made of an insulating material such as a plastic or a conductive material such as a magnesium alloy. Preferably, the case is made by molding if a plastic is used as the case material or by die casting if a magnesium alloy is used.

In the large area reinforced bonding region, a through-hole 5 is formed passing through the front and back plates of the case 2. The through-hole 5, as used in FIG. 1 for example, is for passing a card connection means 10 such as a strap, a wire, or a cord.

The through-hole 5 may have a size of an extent that passes the envisioned card connection means with some leeway and is not limited in its shape. In addition, it may be formed at any position in the reinforcing rib.

The reinforcing rib need not have a large area. The interior space 1a may be expanded to its upper limit as defined by the shape of case, and the through-hole may be formed in the interior space 1a in an island manner. In more detail, a hole is formed in advance in the substrate in a region where electronics parts are not arranged, and cylindrical walls are formed in advance at the case pieces 2a and 2b respectively as integral pieces. When assembling the case, a cylindrical through-hole is thus formed when the two holes face each other.

In this case, owing to the walls, the strength of the case is raised in the middle of the interior space, so the walls of the through-hole function as a reinforcing rib too.

Different materials from that of case 2, e.g., rubber, may be used in the region surrounding the through-hole.

As shown in FIG. 2, the walls of the through-hole are preferably formed by the same or other material as the case so as to seal the interior space 1a. This is for the purpose of preventing condensation, dust, splashed water, oil, alkali substances, and other foreign matter from entering the inside of the card.

In addition, to prevent loss, as shown in FIG. 1, a large card connection means may be used to hold a single IC memory card. Alternatively, a number of IC memory cards may also be held by the same card connection means.

Because the IC memory card according to the first embodiment has a through-hole for passing the card connection means, loss of cards can be effectively prevented even if cards become even smaller in size as recently proposed and even if one person carries around several kinds of cards in order to flexibly deal with various kinds of electronic apparatus.

In addition, as the through-hole is a closed structure and helps raise the strength, an IC memory card of a high reliability can be provided.

By selecting the proper materials for the through-hole, it is possible to suppress the generation of electrostatic charge at the place where the walls rub against the card connection means or raise the efficiency of removing the generated charge for example when the card is loaded in the electronic apparatus.

Second Embodiment

The second embodiment relates to modifications in the shape of an IC memory card.

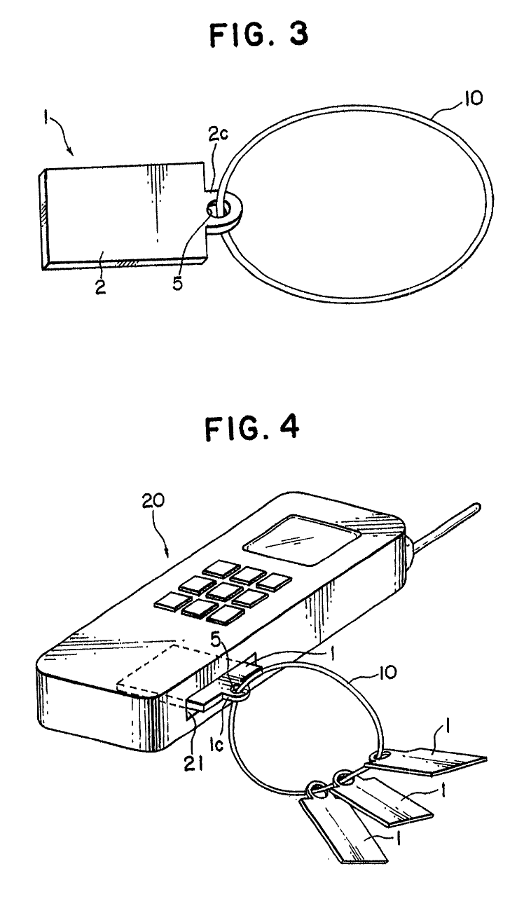

FIG. 3 shows an IC memory card according to the second embodiment held by a card connection means.

The IC memory card 1 has a portion 2c projecting from the main body of the case 2. A through-hole 5 is formed in the projecting portion 2c. With such a shape, there is the advantage that the entire area of the main body of the card can be utilized, as long as this projecting area does not interfere with the loading and unloading of the card to and from the apparatus.

FIG. 4 shows an IC memory card according to the second embodiment loaded in a mobile phone., If part of the IC memory card sticks out from the slot 21 of the mobile phone 20 as shown in FIG. 4, it is preferable to provide the projecting portion 2c at this part. Thus, the loading and unloading of the card to and from the apparatus is not interfered with.

Third Embodiment

The third embodiment relates to a first example of diversification of the function of a through-hole in an IC memory card.

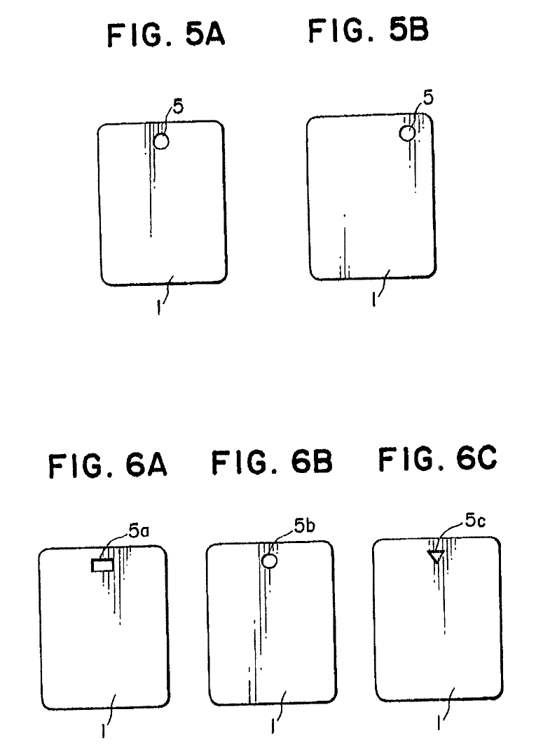

FIGS. 5A and 5B and FIGS. 6A to 6C are plan views of an IC memory card changed in the position and shape of the through-hole according to the type of the card.

In FIGS. 5A and 5B, the positions of the through-holes 5 are changed, while in FIG. 6A to 6C, the shapes of the through-holes 5 are changed.

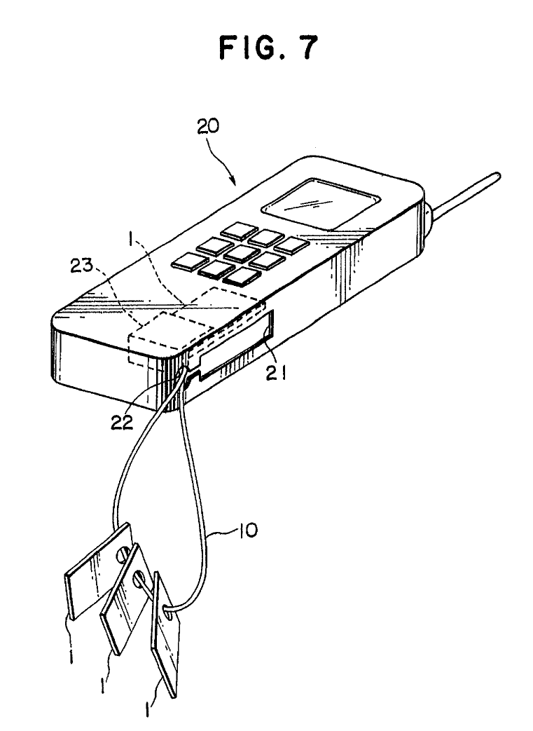

Taking as an example a mobile phone as an electronic apparatus having the function of identifying the type of a card, FIG. 7 shows an IC memory card loaded in such a mobile phone. In this figure, an IC memory card is loaded in the mobile phone 20 while being held by the card connection means 10.

The mobile phone 20 has a slot 21 for loading a card, a space and opening 22 for preventing the card connection means 10 from interfering with the loading and unloading of cards, and a hole detector 23 for detecting the through-hole 5, 5a, 5b or 5c of the inserted IC memory card 1.

A user loads an IC memory card 1 into the slot 21 in the state with the soft material card connection means 10 pulled into the opening 22 communicated with the slot 21. Here, the IC memory card 1 is held in the mobile phone without interference from the card connection means 10. With the card loaded, the through-hole 5, 5a, 5b or 5c is detected by the hole detector 23 provided at a position facing the through-hole of the card. The type of the card is identified according to the position and shape of the detected through-hole. At the same time, the mode or type of information to be written etc. are distinguished.

Therefore, in the third embodiment, even if the cards are small and there are so many types that identification is annoying, because the electronic apparatus is able to automatically identify the type of IC memory card, there is the advantage of easier operation of the electronic apparatus.

Note that in above second and third enbodiments, the IC memory card was loaded in the apparatus while being held by the card connection means, but the IC memory card may also be removed from the card connection means when it is used.

Fourth Embodiment

The fourth embodiment relates to a second example of the diversification of the function of a through-hole of IC memory card.

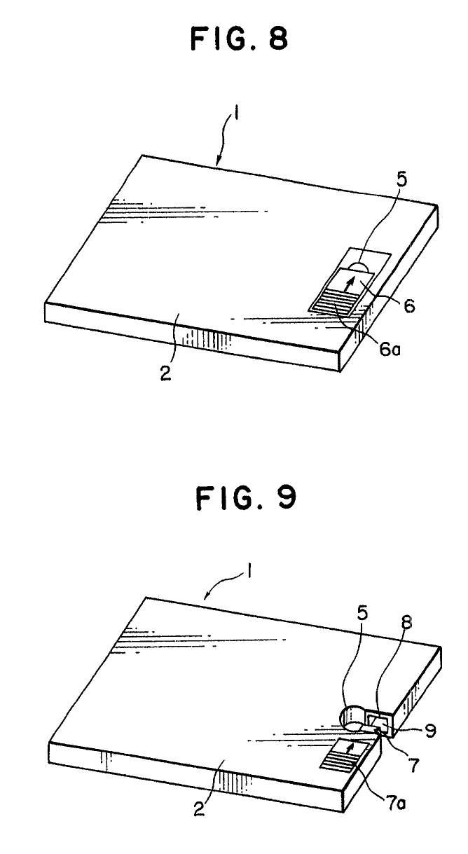

FIG. 8 is a perspective view of an IC memory card according to the fourth embodiment.

In this IC memory card, a slide shutter 6 is provided at one or both of the front and back ends of the through-hole 5. If the operating part 6a formed integrally with the slide shutter 6 and given a suitable slide resistance is pushed and slid by the finger, the slide shutter 6 is closed and the through-hole 5 is covered at one or two ends in the axial direction.

The slide shutter 6 also acts as a switch for preventing reading and overwriting of data. Namely, the electronic apparatus holding the IC memory card 1 controls the ON/OFF state of protection according to whether the through-hole is covered by the slide shutter 6.

In the present embodiment, due to this diversified function of the IC memory card, there are the advantages that mistaken reading and overwriting is prevented and use is easier for the users.

Fifth Embodiment

The fifth embodiment relates to a third example of diversification of the function of a through-hole of an IC memory card.

FIG. 9 is a perspective view of an IC memory card according to the fifth embodiment.

In this IC memory card 1, between the through-hole 5 and one of the sidewalls of the case 2, there is provided a guide 8 cutting through the front and back plates. On one sidewall of the guide 8, there is provided a slide gate 7 that covers the guide 8 by being slid from this sidewall. On the other sidewall of the guide 8, there is a hole for receiving the end of the slide gate 7.

A user presses and moves the operating part 7a formed integrally with the slide gate 7 and given a suitable slide resistance by the finger to open the slide gate 7. In this state, the user inserts the not shown card connection means 10 into the through-hole 5 via the opened guide 8. Then, the user moves the part 7a in the opposite direction to close the slide gate 7, thus preventing detachment of the card connection means 10.

In the present embodiment, due to the provision of the slide gate 7 for opening and closing the guide 8, an individual IC memory card memory card 1 can be easily removed from the card connection means. Therefore, even if there are many IC memory cards connected by a single card connection means, when a specific IC memory card is to be removed, it is not necessary to remove the other IC memory cards first and then put them back after the specific IC memory card is removed. As a result, those many cards will seldom be scattered. There is therefore the advantage that the cards become that much harder to be lost.

Summarizing the effects of the invention, according to the IC memory card and the electronic apparatus according the present invention, because the IC memory card has a through-hole for passing the card connection means, loss of the card can be effectively prevented even if the card is very small in size and many cards are carried at one time. In addition, it becomes much easier to handle and store IC memory cards. Furthermore, by giving the through-hole many other functions, the IC memory card and the electronic apparatus can be made much easier to use.

While the invention has been described by reference to specific embodiments chosen for purposes of illustration, it should be apparent that numerous modifications could be made thereto by those skilled in the art without departing from the basic concept and scope of the invention.

What is claimed is:

1. An IC memory card comprising a case and a semiconductor memory device therein, able to be loaded into an electronic apparatus for exchange of data with the apparatus, able to store data in the semiconductor memory device, and able to be carried outside the apparatus, wherein
a through-hole for passing a card connection means for holding use is formed in the case.

2. An IC memory card according to claim 1, wherein said through-hole is provided in the main body of said case.

3. An IC memory card according to claim 1, wherein said though-hole is provided in a portion of said case projecting outward from the main body of the case.

4. An IC memory card according to claim 1, wherein the walls of said through-hole function as a reinforcing rib when the front and back plates of said case are bonded together.

5. An IC memory card according to claim 1, wherein said case is formed as a single piece including the walls of said through-hole.

6. An IC memory card according to claim 5, wherein said case is comprised of an insulating material.

7. An IC memory card according to claim 5, wherein said case is comprised of a conductive material.

8. An IC memory card according to claim 1, wherein the interior space of the case holding said semiconductor memory device is separated from the exterior space by the walls of said through-hole.

9. An IC memory card according to claim 1, wherein the shape and/or the position of said through-hole is decided according to the type of the IC memory card so that the card can be recognized when it is loaded in said electronic apparatus.

10. An IC memory card according to claim 1, wherein said through-hole is formed in a portion of said IC memory card sticking out of said electronic apparatus when the IC memory card is loaded in the apparatus.

11. An IC memory card according to claim 1, wherein said through-hole is formed in a portion of said IC memory card inside said electronic apparatus when the IC memory card is loaded in the apparatus.

12. An IC memory card according to claim 1, wherein at one or two ends of the through-hole in the axial direction, there is provided a slide shutter that also serves as a protection switch for preventing the data stored in said IC memory card from being read and/or overwritten.

13. An IC memory card according to claim 1, further comprising:
a guide provided between said through-hole and one of the sidewalls of said case and cutting through the front and back plates of the case for passing said card connection means and
a slide gate for opening the guide when said card connection means is to be passed through the through-hole and closing the guide after the card connection means is passed through the through-hole.

14. An IC memory card comprising a case and a semiconductor memory device therein, able to be loaded into an electronic apparatus for exchange of data with the apparatus, able to store data in the semiconductor memory device, and able to be carried outside the apparatus, wherein
a through-hole for passing a card connection means for holding use is formed in the card and
the interior space of the case holding the semiconductor memory device is separated from the exterior space by the walls of the through-hole to create a closed structure.

15. An IC memory card comprising a case and a semiconductor memory device therein, able to be loaded into an electronic apparatus for exchange of data with the apparatus, able to store data in the semiconductor memory device, and able to be carried outside the apparatus,
further comprising a through-hole formed in the case for passing a card connection means for holding use and determined in shape and/or position according to the type of the IC memory card so that the card is capable of being recognized when it is loaded in the electronic apparatus.

16. An IC memory card comprising a case and a semiconductor memory device therein, able to be loaded into an electronic apparatus for exchange of data with the apparatus, able to store data in the semiconductor memory device, and able to be carried outside the apparatus, further comprising:
a through-hole formed in the case for passing a card connection means for holding use; and
a slide-shutter provided at one or both ends of the through-hole in the axial direction and also serving as a protection switch for preventing the data stored in the IC memory card from being read and/or overwritten.

17. An IC memory card comprising a case and a semiconductor memory device therein, able to be loaded into an electronic apparatus for exchange of data with the apparatus, able to store data in the semiconductor memory device, and able to be carried outside the apparatus, further comprising:
a through-hole formed in the case for passing a card connection means for holding use;
a guide provided between the through-hole and one of the sidewalls of the case and through the front and back plates of the case and for passing said card connection means; and
a slide gate for opening the guide when the card connection means is to pass through the through-hole and for closing the guide after the card connection means passes through the through-hole.

18. An electronic apparatus comprising:
a card loading unit for loading an IC memory card storing data in a built-in semiconductor memory device; and
a space for holding a card connection means for holding use close to the card loading unit when the IC memory card is loaded in a state where the card connection means is passed through a through-hole provided in the case.

19. An electronic apparatus comprising:
a card loading unit for loading an IC memory card storing data in a built-in semiconductor memory device; and
a hole detector for detecting a through-hole provided in the case for passing a card connection means for holding use after the IC memory card is loaded.

20. An electronic apparatus according to claim 19, comprising a space for holding a card connection means for holding use close to the card loading unit when the IC memory card is loaded in a state where the card connection means is passed through a through-hole provided in the case.
